(19) United States
(12) Patent Application Publication
(10) Pub. No.: US 2015/0034996 A1
(43) Pub. Date: Feb. 5, 2015

(54) LIGHT-EMITTING DEVICE

(71) Applicant: Epistar Corporation, Hsinchu (TW)

(72) Inventors: Kuang-Ping CHAO, Hsinchu (TW); Wen-Luh LIAO, Hsinchu (TW); Shih-I CHEN, Hsinchu (TW); Chia-Liang HSU, Hsinchu (TW)

(73) Assignee: Epistar Corporation, Hsinchu (TW)

(21) Appl. No.: 13/957,425

(22) Filed: Aug. 1, 2013

(51) Int. Cl. H01L 33/62

(52) U.S. Cl. CPC H01L 33/62
USPC 257/99

(57) ABSTRACT

A light-emitting device comprises a substrate; a first semiconductor stack formed on the substrate; a connecting part formed on the first semiconductor stack; and a plurality of droplets formed near the connecting part, wherein the plurality of droplets comprises a material same as that of the connecting part.

### TECHNICAL FIELD

The application relates to a light-emitting device, and more particularly, to a light-emitting device having a connecting part with a plurality of droplets formed near the connecting part.

### DESCRIPTION OF BACKGROUND ART

FIG. 1 illustrates a cross-sectional view of a conventional light-emitting device 1. The light-emitting device 1 comprises a plurality of semiconductor units 10, which are formed on a substrate 18. The semiconductor units 10 are separated from each other by a trench 16. Each of the plurality of semiconductor units 10 comprises a semiconductor stack 19 comprising a first semiconductor layer 191, a second semiconductor layer 193, and an active layer 192 formed between the first semiconductor layer 191 and the second semiconductor layer 193. Each of the plurality of semiconductor units 10 further comprises a first electrode 14 formed on the first semiconductor layer 191 and a second electrode 15 formed on the second semiconductor layer 193. An insulated layer 13 is formed in the trench 16, and along a sidewall S1, S2 of the semiconductor unit 10 and a surface S3 of the substrate 18. A metal line 11 is conformably formed on the insulated layer 13 to connect the first electrode 14 of one semiconductor unit 10 and the second electrode 15 of another semiconductor unit 10.

Due to the effect of step coverage and stress, crack is easily formed at a position near a corner 10a of the semiconductor unit 10 when the metal line 11 is formed on the semiconductor unit 10. FIG. 2 illustrates a partial enlargement SEM view of an area denoted by the symbol 2A of FIG. 1. The crack position is denoted by an arrow shown in FIG. 2.

### SUMMARY OF THE APPLICATION

A light-emitting device comprises a substrate; a first semiconductor stack formed on the substrate; a connecting part formed on the first semiconductor stack; and a plurality of droplets formed near the connecting part, wherein the plurality of droplets comprises a material same as that of the connecting part.

### BRIEF DESCRIPTION OF THE DRAWINGS

FIG. 1 illustrates a cross-sectional view of a conventional light-emitting device;

FIG. 2 illustrates a partial enlargement SEM view of an area denoted by the symbol 2A of the conventional light-emitting device of FIG. 1;

FIG. 3 illustrates a top view of a light-emitting device in accordance with first embodiment of the present application;

FIG. 4 illustrates an SEM view of a connecting part of FIG. 3;

FIG. 5 illustrates an SEM view of a connecting part of FIG. 3;

FIG. 6 illustrates an SEM view of a connecting part of FIG. 3;

FIG. 7 illustrates a partial enlargement top view of a connecting part of FIG. 3;

FIG. 8 illustrates a cross-sectional view taken along line X-X′ of FIG. 3;

FIG. 9 illustrates a cross-sectional view taken along line Y-Y′ of FIG. 3;

FIG. 10 illustrates a partial enlargement SEM view of an area denoted by the symbol 7A of the light-emitting device of FIG. 9;

FIG. 11 illustrates a cross-sectional view of a light-emitting device in accordance with one embodiment of the present application;

FIG. 12 illustrates a top view of a light-emitting device in accordance with one embodiment of the present application; and

FIG. 13 illustrates a top view of a light-emitting device in accordance with one embodiment of the present application.

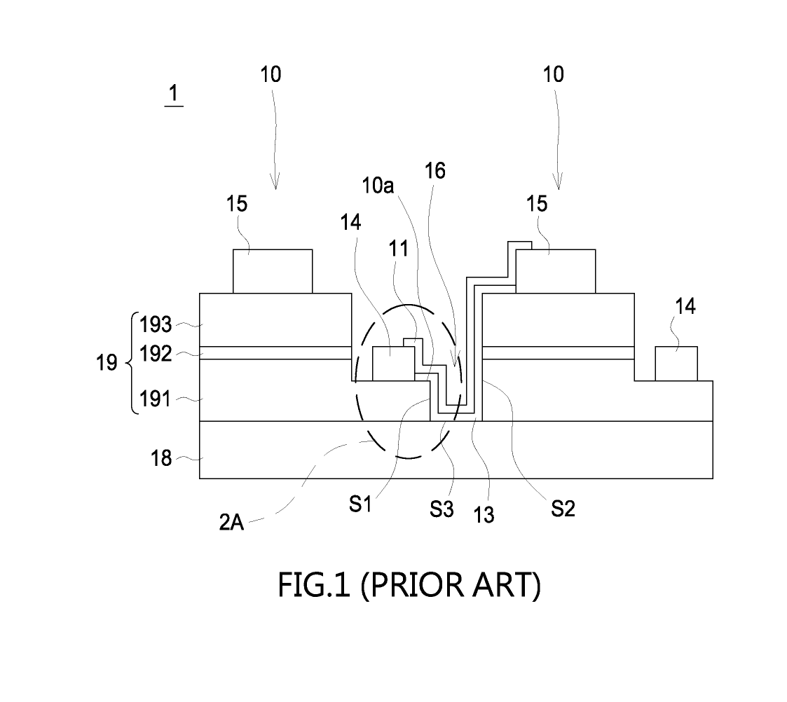

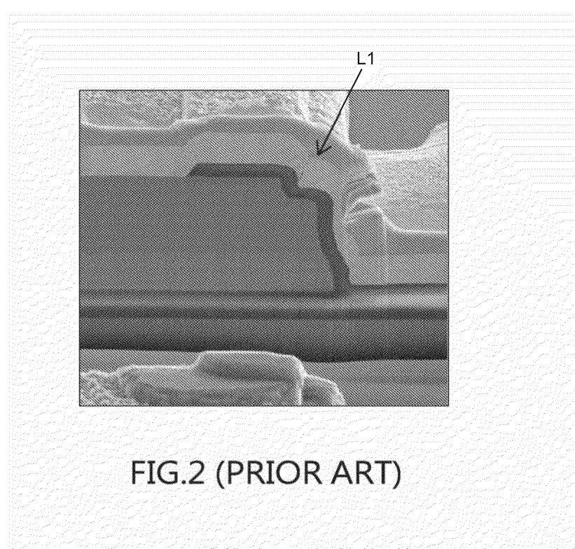

### DETAILED DESCRIPTION OF PREFERRED EMBODIMENTS

The embodiment of the application is illustrated in detail, and is plotted in the drawings. The same or the similar part is illustrated in the drawings and the specification with the same number.

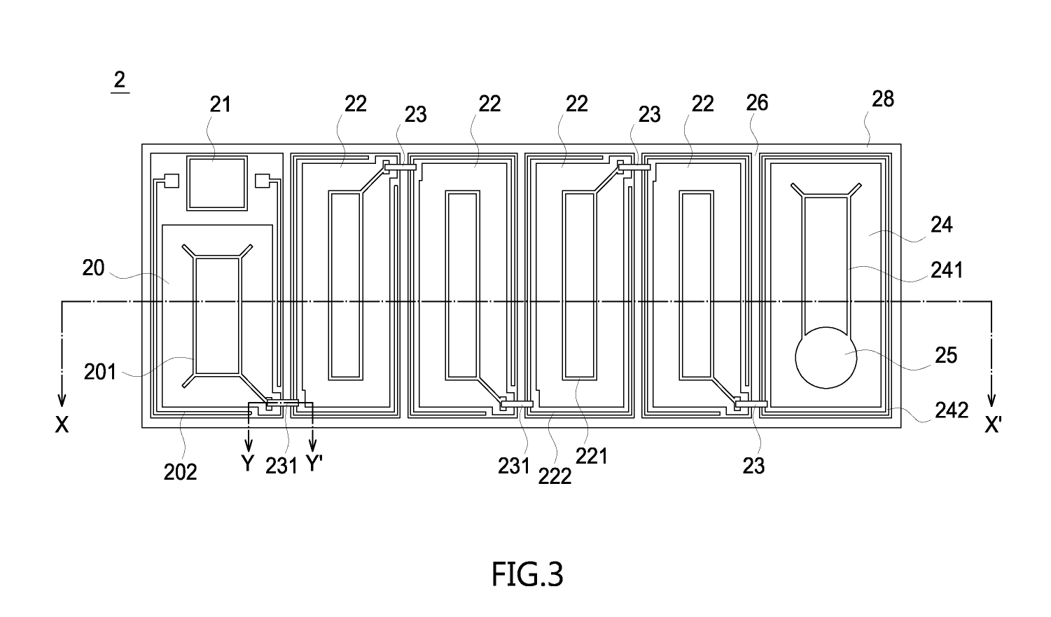

FIG. 3 illustrates a top view of a light-emitting device 2 in accordance with a first embodiment of the present application. The light-emitting device 2, such as a light-emitting diode (LED) or a laser diode (LD), comprises a plurality of semiconductor units, such as the first semiconductor unit 20, the second semiconductor unit 22, and the third semiconductor unit 24, formed on a substrate 28. One or more of the second semiconductor units 22 can be formed between the first semiconductor unit 20 and the third semiconductor unit 24, and FIG. 3 is for example, not a limitation of the application. A trench 26 is formed between two of the semiconductor units and can expose a part of the substrate 28. The substrate 28 can be a growth substrate or a supporting substrate.

A connecting part can be formed on the semiconductor unit or between the semiconductor units for electrical connection. In the embodiment, the connecting part can be an electrode. In an example of the embodiment, the connecting part can be an electrode pad, such as a first electrode pad 21 or a second electrode pad 25. The first electrode pad 21 and the second electrode pad 25 are formed on the semiconductor units for wire bonding or flip-chip type bonding, for example. In another example of the embodiment, the connecting part can be an extension electrode, such as a plurality of first extension electrodes 202, 222, and 242, or a plurality of second extension electrodes 201, 221, and 241. The extension electrodes are formed on the semiconductor units for current spreading, for example. The electrode pad and the extension electrode can be formed discontinuously, such as the first electrode pad 21 and the first extension electrode 202 of the first semiconductor unit 20. Alternatively, the electrode pad and the extension electrode can be formed continuously, such as the second electrode pad 25 and the second extension electrode 241 of the third semiconductor unit 24. In another example of the embodiment, the connecting part can be a connecting electrode, such as a plurality of connecting electrodes 231. The connecting electrodes 231 are formed between the semiconductor units, across the trench 26 to electrically connect adjacent two semiconductor units, such as the first semiconductor unit 20 and the second semiconductor unit 22.

The electrode pad, extension electrode, or the connecting electrode are patterned on the semiconductor unit without use of masks. The electrode pad, extension electrode, or the connecting electrode can be formed by spraying a liquid medium onto the semiconductor unit through a nozzle (not shown). An amount of the nozzle can be one or more. A pattern of the first electrode pad 21, the second electrode pad 25 or the connecting electrode 231 is accomplished by disposing the light-emitting device 2 on a computer controlled platform (not shown) while a position of the nozzle is fixed, or by moving the nozzle while a position of the light-emitting device 2 is fixed.

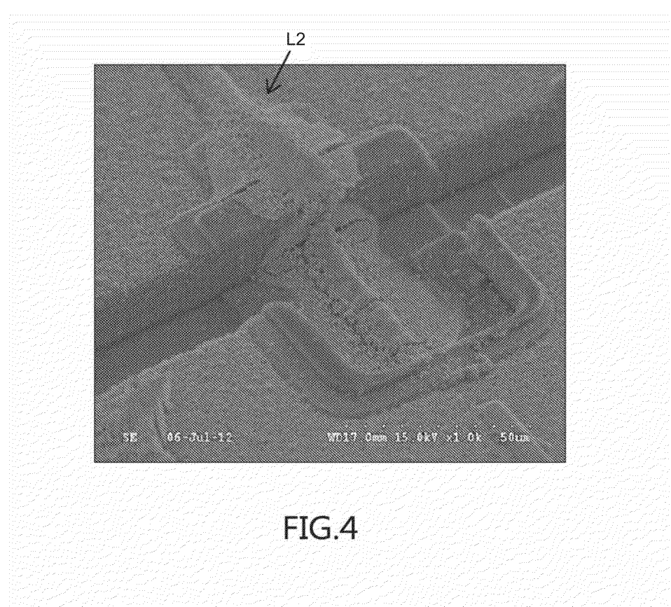

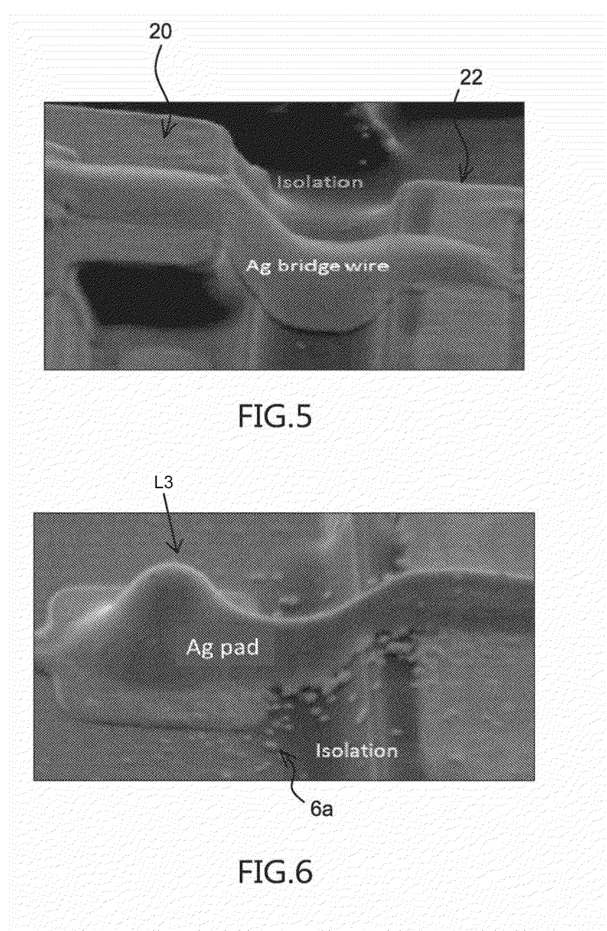

The liquid medium comprises solid particles, such as metal nanoparticles, and solution, such as solvent. The solid particles and the solution are simultaneous deposed on the semiconductor unit through inject printing, such as aerosol jet printing. A resistivity of the metal nanoparticles is below 1×10⁻⁷ Ωm. After the solid particles and the solution being deposed on the semiconductor unit, the solution is driven out by heating and the solid particles is left on the semiconductor unit. A surface where the liquid medium is sprayed on of the semiconductor unit is hydrophilic treated, such as O₂ plasma, before spraying the liquid medium. FIG. 4 illustrates an SEM view of one connecting part of FIG. 3 without hydrophilic treating the surface of the semiconductor unit before spraying the liquid medium. Because the surface of the semiconductor unit is hydrophobic, the liquid medium is not easily adhered to the surface of the semiconductor unit. The connecting part denoted by an arrow shown in FIG. 4 has a rough surface profile which is not easy for the connecting part to adhere the semiconductor unit. FIG. 5 is an SEM view of one connecting electrode of FIG. 3. In FIG. 5, the connecting electrode can be a silver bridge wire to connect the first semiconductor unit 20 and the second semiconductor unit 22. FIG. 6 is an SEM view of the electrode pad of FIG. 3. In an example of FIG. 6, the electrode pad can be a silver pad. A top surface of the electrode pad is curved as denoted by an arrow shown in FIG. 6. As viewed from the top of the electrode pad, the electrode pad comprises a plan-view shape of circle or ellipse. The electrode pad also comprises a cross sectional shape of curve, which has a tapered width and the width decreases towards the top surface of the electrode pad. When the electrode pad is formed by spraying the liquid medium on the semiconductor unit, a plurality of droplets 6a is formed near the electrode pad, and the droplets 6a comprise a material same as that of the electrode pad.

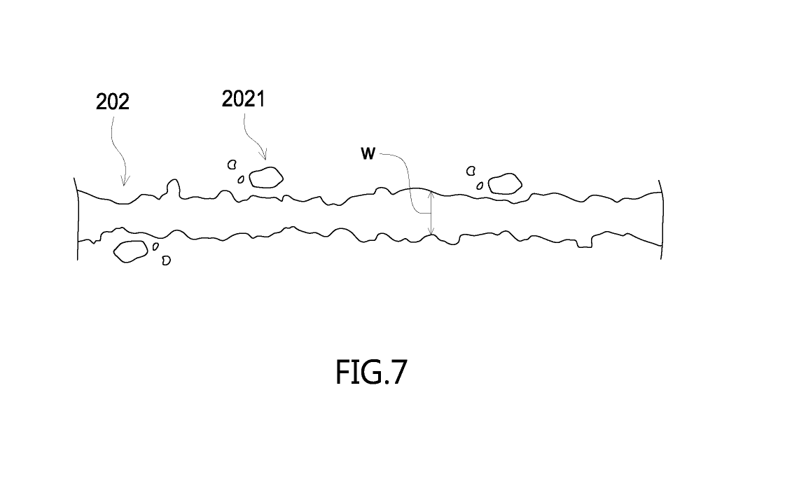

FIG. 7 is a part of an enlarged diagram of the extension electrode such as the first extension electrode 202 in FIG. 3. The first extension electrode 202 comprises an uneven width W. When the extension electrode is formed by spraying the liquid medium on the semiconductor unit, a plurality of droplets is formed near the connecting part. For example, a plurality of droplets 2021 is formed near the first extension electrode 202 as shown in FIG. 7. The plurality of droplets 2021 comprises a material same as that of the first extension electrode 202. A diameter of one of the plurality of droplets, such as the droplet 2021 of FIG. 7, is smaller than 10 μm, preferably smaller than 5 μm.

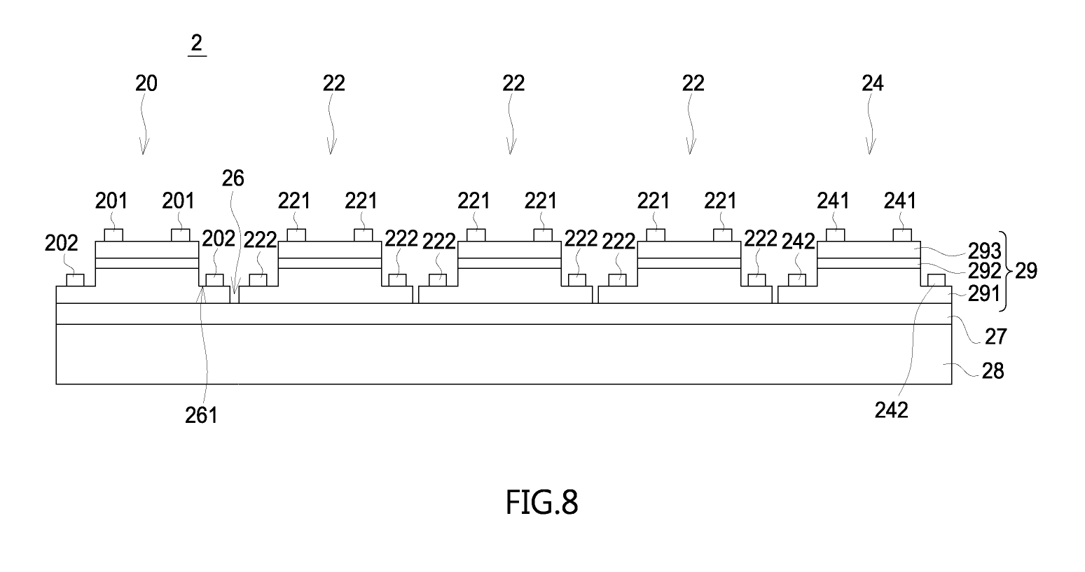

FIG. 8 illustrates a cross-sectional view taken along line X-X′ of FIG. 3. Each semiconductor unit comprises a semiconductor stack 29 comprising a first semiconductor layer 291 and a second semiconductor layer 293. When the light-emitting device 2 is a device capable of transforming electricity into photon energy, such as a light-emitting diode (LED) or a laser diode (LD), the light-emitting device 2 further comprises an active layer 292 formed between the first semiconductor layer 291 and the second semiconductor layer 293. The material of the first semiconductor layer 291 can be group III-V semiconductor material optionally doped with p-type dopant or n-type dopant. The material of the second semiconductor layer 293 can be group III-V semiconductor material optionally doped with p-type dopant or n-type dopant. The conductivity of the first semiconductor layer 291 and the conductivity of the second semiconductor layer 293 are different, preferably opposite. The active layer 292 comprises a single heterostructure (SH), a double heterostructure (DH), or a multi-quantum well (MQW) structure. The semiconductor stack 29 may be formed by a known epitaxy method such as metallic-organic chemical vapor deposition (MOCVD) method, a molecular beam epitaxy (MBE) method, or a hydride vapor phase epitaxy (HVPE) method.

A layer 27 is optionally formed between the semiconductor stack 29 and the substrate 28. The layer 27 can be a reflective layer including but is not limited to metal, dielectric, semiconductor, or the combination thereof. The material of the metal includes but is not limited to Al, Au, Pt, Zn, Ag, Ni, Ge, In, Sn, or alloy of them. The dielectric material includes but is not limited to AlOₓ, SiOₓ, SiN_{y}, or SiOₓN_{y}. The layer 27 also can be an adhesive layer including but is not limited to AlOₓ, SiOₓ, spin on glass (SOG), silicone, polyimide (PI), benzocyclobutene (BCB), perfluorocyclobutane (PFCB), or epoxy.

A mesa 261 is formed by etching the semiconductor stacks, and the mesa 261 is formed on the first semiconductor layer 291. The second extension electrodes 201, 221, and 241 are respectively formed on and connected to the second semiconductor layer 293 of the first semiconductor unit 20, the second semiconductor unit 22, and the third semiconductor unit 24. The first extension electrodes 202, 222, and 242 are respectively formed on the mesa 261 and respectively connected to the first semiconductor layer 291 of the first semiconductor unit 20, the second semiconductor unit 22, and the third semiconductor unit 24. The electrons provided from the n-type semiconductor layer, such as the first semiconductor layer 291, and the holes provided from the p-type semiconductor layer, such as the second semiconductor layer 293, combine in the active layer 292 to emit a light under an external electrical current provided through the plurality of first extension electrodes 202, 222, and 242, and the plurality of second extension electrodes 201, 221, and 241.

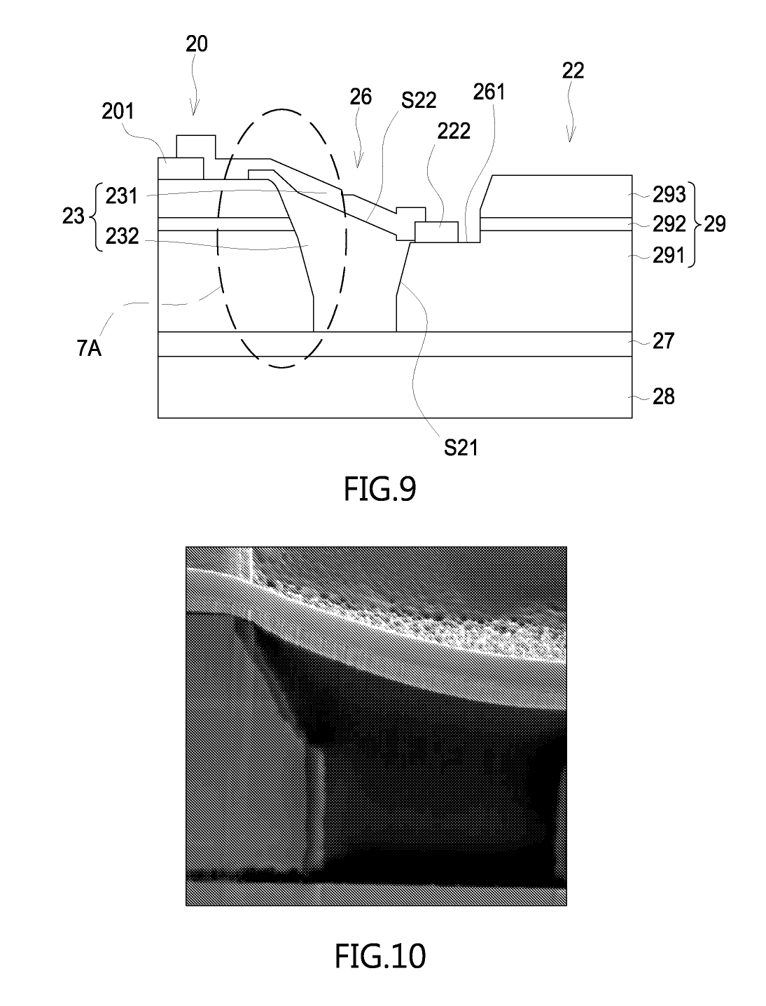

FIG. 9 illustrates a cross-sectional view taken along line Y-Y′ of FIG. 3. A sidewall S21 of the trench 26 comprises an inclined surface, a vertical surface, or the combination thereof. FIG. 9 illustrates an example that sidewall S21 of the trench 26 comprises the inclined surface and the vertical surface. The connecting part 23 is formed across the trench 26. The connecting part 23 comprises an insulated portion 232, and the connecting electrode 231 which is formed on the insulated portion 232.

A top surface S22 of the insulated portion 232 can be flat, or inclined. FIG. 9 illustrates an example that the top surface S22 of the insulated portion 232 is inclined. As shown in FIG. 9, the insulated portion 232 fills up the trench 26 with a liquid medium. Part of the liquid medium overflows onto the mesa 261. The liquid medium comprises insulated material and solvent. The solvent is removed by thermal curing. The insulated portion 232 is provided to protect the surface of the semiconductor unit 20, 22, or to insulate the semiconductor unit 20, 22. The insulated portion 232 comprises an insulated material having transmittance larger than 80% at 400 nm, and having refractive index larger than 1.4 at 400 nm. By selection of a liquid medium with transmittance larger than 80% at 400 nm, light extraction from the light-emitting device 2 is enhanced.

The conductive portion 231 is conformably formed on the insulated portion 232 by spraying a liquid medium comprising a solvent, and metal nanoparticles dispersed in the solvent. The conductive portion 231 has an uneven width in a top view. One end of the connecting electrode 231 is connected to the second extension electrode 201, and another end of the connecting electrode 231 is connected to the first extension electrode 222.

FIG. 10 illustrates a partial enlargement view of SEM of an area denoted by the symbol 7A of the light-emitting device of FIG. 9.

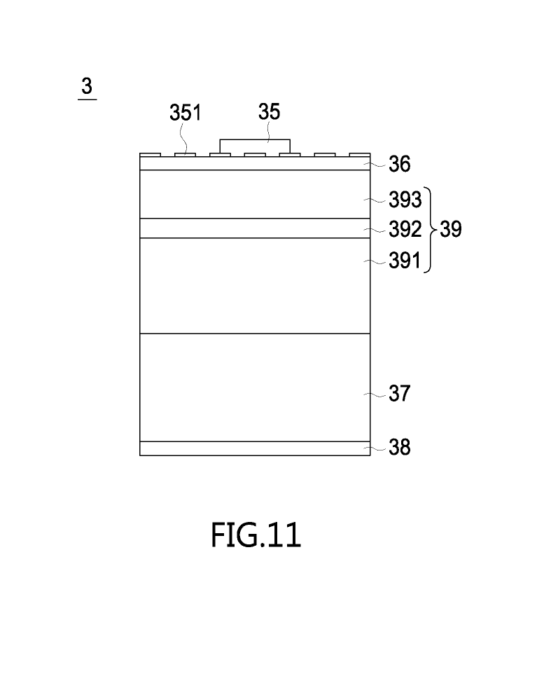

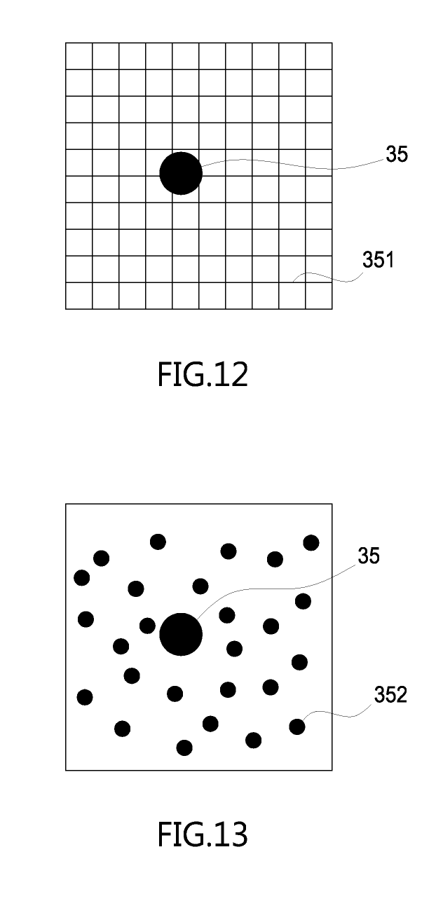

FIG. 11 illustrates a cross-sectional view of a light-emitting device 3 in accordance with a second embodiment of the present application. The light-emitting device 3, such as a light-emitting diode (LED) or a laser diode (LD), comprises a structure approximately similar to that of the semiconductor units, such as the first semiconductor unit 20, the second semiconductor unit 22, and the third semiconductor unit 24 shown in the first embodiment of FIG. 8. The light-emitting device 3 comprises a substrate 37 and a semiconductor stack 39 formed on the substrate 37. The substrate 37 can be a growth substrate or a supporting substrate. The semiconductor stack 39 comprises a first semiconductor layer 391 and a second semiconductor layer 393. When the light-emitting device 3 is a light-emitting diode (LED) or a laser diode (LD), The light-emitting device 3 further comprises an active layer 392 formed between the first semiconductor layer 391 and the second semiconductor layer 393. One or more connecting parts, such as a first electrode pad 38 and a second electrode pad 35 are formed on the semiconductor stack 39, and respectively electrically connected to the first semiconductor layer 391 and the second semiconductor layer 393 when an electrical energy is supplied to the light-emitting device 3. The light-emitting device 3 optionally comprises a current spreading layer 36 formed on the semiconductor stack 39, between the semiconductor stack 39 and the second electrode 35. The material of the current spreading layer 36 comprises transparent oxide material, such as ITO or IZO, semiconductor material, such GaP, or thin metal material. In order to increase the current spreading, one or more connecting parts, such as a plurality of extension electrodes 351 can be formed on the light-emitting device 3, electrically connected to the second electrode pad 35. A pattern of the plurality of extension electrodes 351 can be formed in a regular pattern, such as a grid pattern shown in FIG. 12, or an irregular pattern, such as a plurality of dots 352 shown in FIG. 13.

A manufacturing method of the connecting part shown in the first embodiment or the second embodiment comprises the following steps:

Step 1. providing a substrate;

Step 2. forming a semiconductor stack on the substrate;

Step 3. treating a surface of the semiconductor stack to be hydrophilic, for example, O₂ plasma treating;

Step 4. spraying a liquid medium on the surface of the semiconductor stack, wherein the liquid medium comprises solution, and one of conductive materials and insulated materials, the conductive material comprises metal nanoparticles having resistivity below 1×10⁻⁷ Ωm, the insulated material has transmittance larger than 80% at 400 nm or a refractive index larger than 1.4 at 400 nm; and

Step 5. heating the semiconductor stack under a temperature above 150° C.

The principle and the efficiency of the present application illustrated by the embodiments above are not the limitation of the application. Any person having ordinary skill in the art can modify or change the aforementioned embodiments. Therefore, the protection range of the rights in the application will be listed as the following claims.

1. A light-emitting device, comprising:
a substrate;
a first semiconductor stack formed on the substrate;
a connecting part formed on a surface of the first semiconductor stack; and
a plurality of droplets formed on the surface of the first semiconductor stack and spaced apart from the connecting part, wherein the plurality of droplets comprises a material same as that of the connecting part.

2. The light-emitting device of claim 1, wherein a diameter of one of the plurality of droplets is smaller than 10 μm.

3. The light-emitting device of claim 1, wherein the connecting part is patterned and formed on the first semiconductor stack.

4. The light-emitting device of claim 1, wherein the connecting part comprises a conductive portion and an insulated portion.

5. The light-emitting device of claim 1, wherein the connecting part comprises an electrode pad or an extension electrode.

6. The light-emitting device of claim 4, wherein the conductive portion is conformably formed on the insulated portion.

7. The light-emitting device of claim 1, wherein the connecting part comprises metal nanoparticles.

8. The light-emitting device of claim 7, wherein a resistivity of the metal nanoparticles is below 1×10⁻⁷ Ωm.

9. The light-emitting device of claim 5, wherein a top surface of the electrode pad is curved.

10. The light-emitting device of claim 5, wherein the extension electrode comprises an uneven width.

11. The light-emitting device of claim 5, wherein the electrode pad comprises a plan-view shape of circle or ellipse.

12. The light-emitting device of claim 5, wherein the electrode pad comprises a cross sectional shape of curve.

13. The light-emitting device of claim 9, wherein the electrode pad comprises a tapered width decreasing towards the top surface of the electrode pad.

14. The light-emitting device of claim 1, further comprising a second semiconductor stack formed on the substrate, and a trench formed between the first semiconductor stack and the second semiconductor stack, wherein the connecting part is across the trench.

15. The light-emitting device of claim 14, wherein the trench comprises a vertical surface and an inclined surface.

16. The light-emitting device of claim 14, wherein a top surface of the connecting part comprises an inclined surface.

17. The light-emitting device of claim 14, wherein the connecting part fills up the trench.

18. The light-emitting device of claim 15, further comprising a first electrode formed on the first semiconductor stack and a second electrode formed on the second semiconductor stack, wherein the inclined surface is lower than a top surface of the first electrode or the second electrode.

19. The light-emitting device of claim 1, wherein the connecting part comprises an insulated material having transmittance larger than 80% at 400 nm and/or having a refractive index larger than 1.4 at 400 nm.

20. The light-emitting device of claim 3, wherein the connecting part forms a grid pattern or a plurality of dots on the first semiconductor stack.
